(19) United States
(12) Patent Application Publication
(10) Pub. No.: US 2026/0005656 A1
(43) Pub. Date: Jan. 1, 2026

(54) Switched Capacitor Based Amplifier Circuitry with Improved Reliability

(71) Applicant: Apple Inc., Cupertino, CA (US)

(72) Inventors: Amir Ghaffari, San Jose, CA (US); Bevin G Perumana, Anaheim, CA (US); Mahmood Baraani Dastjerdi, San Jose, CA (US); Amirpouya Kavousian, San Jose, CA (US); Saikat Sarkar, Irvine, CA (US); Tirdad Sowlati, Irvine, CA (US)

(21) Appl. No.: 18/754,951

(22) Filed: Jun. 26, 2024

(51) Int. Cl. H03F 3/195; H03F 1/22

(52) U.S. Cl. CPC H03F 3/195; H03F 1/223; H03F 2200/267; H03F 2200/451

(57) ABSTRACT

Wireless circuitry is provided that includes radio-frequency amplifier circuitry. The amplifier circuitry can include multiple capacitors, each of which has a first terminal coupled to an antenna and a second terminal. The amplifier circuitry can include at least one capacitor switching circuit coupled to the second terminal of one of the capacitors. The capacitor switching circuit can include a pull-up transistor configured to receive a first voltage signal and a cascode transistor coupled between the pull-up transistor and an output of the capacitor switching circuit. The cascode transistor can be configured to receive a second voltage signal that toggles while the at least one capacitor switching circuit is configured to operate in at least a plurality of swing modes.

### FIELD

This disclosure relates generally to electronic devices, including electronic devices with wireless communications circuitry.

### BACKGROUND

Electronic devices can be provided with wireless communications capabilities. An electronic device with wireless communications capabilities has wireless communications circuitry with one or more antennas. Wireless transceiver circuitry in the wireless communications circuitry uses the antennas to transmit and receive radio-frequency signals.

Radio-frequency signals transmitted by an antenna can be fed through one or more power amplifiers, which are configured to amplify low power analog signals to higher power signals more suitable for transmission through the air over long distances. A radio-frequency power amplifier can include multiple switched capacitors. It can be challenging to design switched capacitor based radio-frequency amplifiers.

### SUMMARY

An aspect of the disclosure provides amplifier circuitry that includes a plurality of capacitors and at least one capacitor switching circuit coupled to a capacitor in the plurality of capacitors. The at least one capacitor switching circuit includes a pull-up transistor configured to receive a first voltage signal and a first cascode transistor coupled between the pull-up transistor and an output of the at least one capacitor switching circuit, the first cascode transistor being configured to receive a second voltage signal that toggles while the at least one capacitor switching circuit is configured to operate in at least a first mode and a second mode different than the first mode. The first voltage signal can toggle between a first voltage level and a second voltage level during the first mode, whereas the second voltage signal can toggle between the second voltage level and a third voltage level less than the second voltage level during the second mode. The first voltage signal can be fixed at the first voltage level during the second mode, whereas the second voltage signal can toggle between the third voltage level and a fourth voltage level less than the third voltage level during the second mode. The at least one capacitor switching circuit can further be configured to operate in a third mode, where the first voltage signal is fixed at the first voltage level during the third mode and where the second voltage signal is fixed at the fourth voltage level during the third mode.

An aspect of the disclosure provides a method of operating a switching circuit coupled to one of a plurality of capacitors in a radio-frequency amplifier. The method includes conveying a first voltage signal to a gate terminal of a pull-up transistor, conveying a second voltage signal to a gate terminal of a first cascode transistor coupled between the pull-up transistor and an output of the switching circuit, conveying a third voltage signal to a gate terminal of a second cascode transistor, and conveying a fourth voltage signal to a gate terminal of a pull-down transistor, where the second voltage signal and the third voltage signal are toggled between different voltage levels during at least a first mode of the switching circuit. The method can further include toggling the first voltage signal between first and second voltage levels during the first mode, toggling the second voltage signal between the second voltage level and a third voltage level less than the second voltage level during the first mode, toggling the third voltage signal between the third voltage level and a fourth voltage level less than the third voltage level during the first mode, and toggling the fourth voltage signal between the fourth voltage level and a fifth voltage level less than the fourth voltage level during the first mode.

The method can further include fixing the first voltage signal at the first voltage level during a second mode different than the first mode, toggling the second voltage signal between the third and fourth voltage levels during the second mode, toggling the third voltage signal between the fourth and fifth voltage levels during the second mode, and fixing the fourth voltage signal at the fourth voltage level during the second mode. The method can further include fixing the first voltage signal at the first voltage level during a third mode different than the first and second modes, fixing the second voltage signal at the fourth voltage level during the third mode, fixing the third voltage signal at the fourth voltage level during the third mode, and fixing the fourth voltage signal at the fifth voltage level during the third mode.

An aspect of the disclosure provides a switching circuit that includes an output coupled to one of a plurality of capacitors, a pull-up transistor, a pull-down transistor, and two or more cascode transistors coupled in series between the pull-up and pull-down transistors and operable to receive time-varying voltage signals. During a first swing mode, the pull-up transistor can be configured to receive a first voltage signal toggling between a first voltage level and a second voltage level, a first of the cascode transistors can be configured to receive a second voltage signal toggling between the second voltage level and a third voltage level less than the second voltage level, a second of the cascode transistors can be configured to receive a third voltage signal toggling between the third voltage level and a fourth voltage level less than the third voltage level, and the pull-down transistor can be configured to receive a fourth voltage signal toggling between the fourth voltage level and a fifth voltage level less than the fourth voltage level. During a second mode, the first voltage signal can be fixed at the first voltage level, the second voltage signal can toggle between the third and fourth voltage levels, the third voltage signal can toggle between the fourth and fifth voltage levels, and the fourth voltage signal can be fixed at the fourth voltage level. During a third swing mode, the first voltage signal can be fixed at the first voltage level, the second voltage signal can be fixed at the fourth voltage level, the third voltage signal can be fixed at the fourth voltage level, and the fourth voltage signal can be fixed at the fifth voltage level.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having amplifiers in accordance with some embodiments.

FIG. 3 is a diagram of illustrative transmit circuitry in accordance with some embodiments.

FIG. 4 is a diagram of illustrative switched capacitor based radio-frequency amplifier circuitry in accordance with some embodiments.

FIG. 5 is a diagram showing illustrative swing modes for operating one or more capacitor switching circuits in the switched capacitor based radio-frequency amplifier circuitry of FIG. 4 in accordance with some embodiments.

FIG. 6 is a circuit diagram of an illustrative capacitor switching circuit operable in a high swing mode in accordance with some embodiments.

FIG. 7 is a timing diagram illustrating an operation of the capacitor switching circuit of FIG. 6 in accordance with some embodiments.

FIG. 8 is a circuit diagram of an illustrative capacitor switching circuit operable in a low swing mode in accordance with some embodiments.

FIG. 9 an illustrative capacitor switching circuit operable in a zero-swing mode in accordance with some embodiments.

FIG. 10 is a circuit diagram of an illustrative cascode driver circuit being configured in a high swing mode in accordance with some embodiments.

FIG. 11 is a circuit diagram of an illustrative cascode driver circuit being configured in a low swing mode in accordance with some embodiments.

FIG. 12 is a circuit diagram of an illustrative capacitor switching circuit having more than two cascode transistors in accordance with some embodiments.

### DETAILED DESCRIPTION

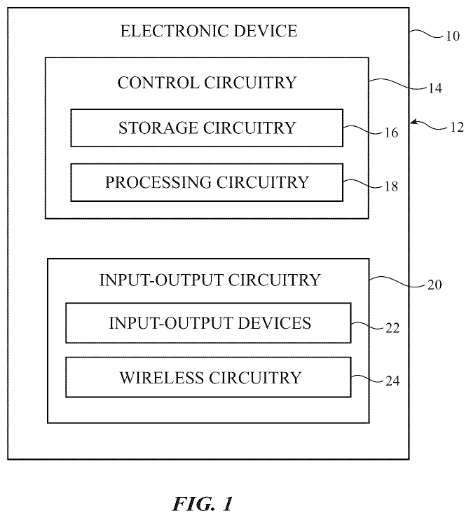

An electronic device such as device 10 of FIG. 1 may be provided with wireless circuitry. The wireless circuitry can include a switched capacitor based radio-frequency amplifier having capacitors and a plurality of switching circuits coupled to the capacitors. Each of the switching circuits can include a pull-down transistor, a pull-up transistors, and two or more cascode transistors coupled in series with the pull-down and pull-up transistors. A toggling control signal can have a voltage swing that is evenly distributed among the pull-up transistor, the pull-down transistor, and the cascode transistors while operating the switching circuits in various swing modes (e.g., a high swing mode, a low swing mode, and a zero swing mode). Configuring and operating a switched capacitor based radio-frequency amplifier in this way can be technically advantageous and beneficial to provide improved power efficiency by producing the same amount of output power at a lower supply voltage.

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols-sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G protocols, etc.), antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHZ), and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), other centimeter or millimeter wave frequency bands between 10-300 GHz, near-field communications frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

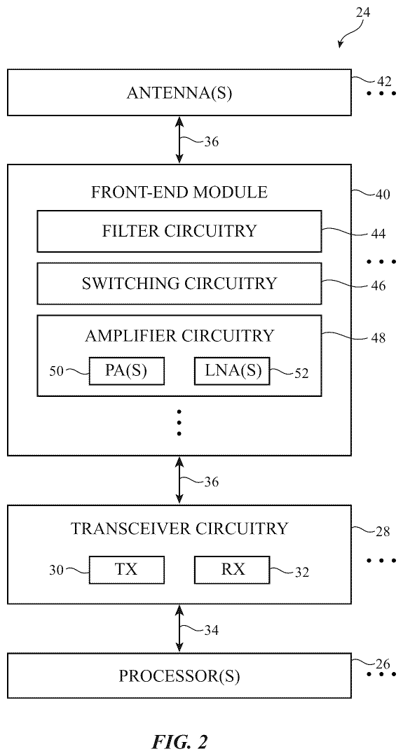

FIG. 2 is a diagram showing illustrative components within wireless circuitry 24. As shown in FIG. 2, wireless circuitry 24 may include a processor such as processor 26, radio-frequency (RF) transceiver circuitry such as radio-frequency transceiver 28, radio-frequency front end circuitry such as radio-frequency front end module (FEM) 40, and antenna(s) 42. Processor 26 may be a baseband processor, application processor, general purpose processor, microprocessor, microcontroller, digital signal processor, host processor, application specific signal processing hardware, or other type of processor. Processor 26 may be coupled to transceiver 28 over path 34. Transceiver 28 may be coupled to antenna 42 via radio-frequency transmission line path 36. Radio-frequency front end module 40 may be disposed on radio-frequency transmission line path 36 between transceiver 28 and antenna 42.

In the example of FIG. 2, wireless circuitry 24 is illustrated as including only a single processor 26, a single transceiver 28, a single front end module 40, and a single antenna 42 for the sake of clarity. In general, wireless circuitry 24 may include any desired number of processors 26, any desired number of transceivers 28, any desired number of front-end modules 40, and any desired number of antennas 42. Each processor 26 may be coupled to one or more transceiver 28 over respective paths 34. Each transceiver 28 may include a transmitter circuit 30 configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front-end module 40 disposed thereon. If desired, two or more front end modules 40 may be disposed on the same radio-frequency transmission line path 36. If desired, one or more of the radio-frequency transmission line paths 36 in wireless circuitry 24 may be implemented without any front-end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processor 26 may provide transmit signals (e.g., digital or baseband signals) to transceiver 28 over path 34. Transceiver 28 may further include circuitry for converting the transmit (baseband) signals received from processor 26 into corresponding radio-frequency signals. For example, transceiver circuitry 28 may include mixer circuitry for up-converting (or modulating) the transmit (baseband) signals to radio frequencies prior to transmission over antenna 42. The example of FIG. 2 in which processor 26 communicates with transceiver 28 is illustrative. In general, transceiver 28 may communicate with a baseband processor, an application processor, general purpose processor, a microcontroller, a microprocessor, or one or more processors within circuitry 18. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front-end module 40. Antenna 42 may transmit the radio-frequency signals to external wireless equipment by radiating the radio-frequency signals into free space.

Front end module (FEM) 40 may include radio-frequency front end circuitry that operates on the radio-frequency signals conveyed (transmitted and/or received) over radio-frequency transmission line path 36. FEM 40 may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifier circuits 50 and/or one or more low-noise amplifier circuits 52), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other circuitry that operates on the radio-frequency signals transmitted and/or received by antenna 42. Each of the front-end module components may be mounted to a common (shared) substrate such as a rigid printed circuit board substrate or flexible printed circuit substrate. If desired, the various front end module components may also be integrated into a single integrated circuit chip. If desired, amplifier circuitry 48 and/or other components in front end 40 such as filter circuitry 44 may also be implemented as part of transceiver circuitry 28.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front end module 40. For example, transceiver 28 may be formed on another substrate such as the main logic board of device 10, a rigid printed circuit board, or flexible printed circuit that is not a part of front-end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processor 26 and/or portions of transceiver 28 (e.g., a host processor on transceiver 28) may form a part of control circuitry 14. Control circuitry 14 (e.g., portions of control circuitry 14 formed on processor 26, portions of control circuitry 14 formed on transceiver 28, and/or portions of control circuitry 14 that are separate from wireless circuitry 24) may provide control signals (e.g., over one or more control paths in device 10) that control the operation of front-end module 40.

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHZ, 3G bands, 4G LTE bands, 5G New Radio Frequency Range 1 (FR1) bands below 10 GHz, 5G New Radio Frequency Range 2 (FR2) bands between 20 and 60 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

As described above, front end module 40 may include one or more power amplifiers (PA) circuits 50 in the transmit (uplink) path. A power amplifier 50 (sometimes referred to as radio-frequency power amplifier, transmit amplifier, or amplifier) may be configured to amplify a radio-frequency signal without changing the signal shape, format, or modulation. Amplifier 50 may, for example, be used to provide 10 dB of gain, 20 dB of gain, 10-20 dB of gain, less than 20 dB of gain, more than 20 dB of gain, or other suitable amounts of gain.

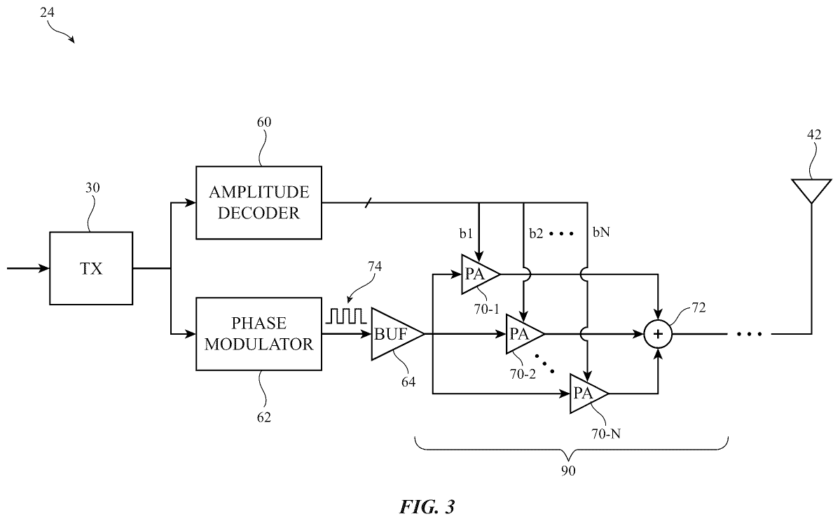

FIG. 3 is a diagram of an illustrative transmit path of wireless circuitry 24 in accordance with some embodiments. As shown in FIG. 3, the transmit path can include a transmitter circuit 30, a decoder circuit such as an amplitude decoder 60, a modulation circuit such as a phase modulator 62, a buffer 64 coupled at an output of phase modulator 62, a plurality of amplifier circuits such as amplifier circuits 70, a signal combiner 72, and one or more antennas 42. Transmitter circuit 30 (see, e.g., transmitter 30 within transceiver 28 in FIG. 2) may be configured to output uplink or transmit signals. The amplifier circuits 70 can include N amplifier circuits 70-1, 70-2, . . . , and 70-N, where N can represent an integer that is greater than one, 2-10, 10-20, 20-50, 50-100, or greater than 100.

The transmit signals may be conveyed to amplitude decoder 60 and phase modulator 62. Amplitude decoder 60 can generate, based on the transmit signals, corresponding digital control signals b1, b2, . . . , bN for controlling the respective N amplifier circuits 70. In the example of FIG. 3, control signal b1 can be fed to a control terminal of amplifier circuit 70-1, control signal b2 can be fed to a control terminal of amplifier circuit 70-2, and control signal bN can be fed to a control terminal of amplifier circuit 70-N. One or more of the control signals b1-bN can be asserted (e.g., driven high) to selectively activate or enable one or more amplifier circuits 70. One or more of the control signals b1-bN can be deasserted (e.g., driven low) to selectively deactivate or disable one or more amplifier circuits 70. By selectively controlling a number of amplifier circuits 70 that is activated, amplitude decoder 60 can control the amplitude of the signal collectively output from amplifier circuits 70.

Phase modulator 62 can generate a corresponding oscillating signal 74 based on the transmit signals. The oscillating signal 74 can optionally be buffered using buffer circuit 64 coupled at the output of phase modulator 62. Buffer circuit 64, sometimes referred to as an oscillating signal driver, can help drive oscillating signal 74 onto corresponding inputs of the N amplifier circuits 70. Configured in this way, phase modulator 62 can control the timing of oscillating signals 74 to control or shift the phase of the signal collectively output from amplifier circuits 70.

The N amplifier circuits 70 can receive the oscillating signal 74, but only an activated portion of the N amplifier circuits 70 will output amplified signals to combiner 72. A portion of the N amplifier circuits 70 can optionally be deactivated (e.g., by deasserting one or more of the digital control signals b1-bN). Combiner 72 can be configured to receive the amplified signals from one or more amplifier circuits 70 and to add/sum the amplified signals to produce a combined amplified signal at its output. Combiner 72 is thus sometimes referred to as a summing or adder circuit. The combined signal output from combiner 72 can be fed to one or more antennas 42 for wireless transmission. If desired, one or more additional radio-frequency front-end components can be coupled between combiner 72 and antenna(s) 42 (see, e.g., front-end components 40 in FIG. 2).

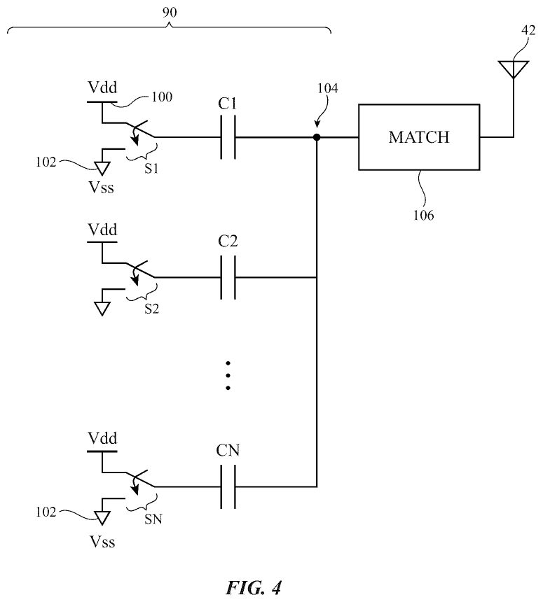

In accordance with some embodiments, the plurality of amplifier circuits 70 and combiner 72 can represent a switched capacitor radio-frequency (RF) amplifier 90. A switched capacitor based RF amplifier 90, sometimes referred to herein more generically as capacitor based amplifier circuitry, can include a plurality of capacitors that are selectively switched in and out of use via respective switches. FIG. 4 is a diagram of illustrative switched-capacitor based radio-frequency amplifier circuitry 90. As shown in FIG. 4, amplifier circuitry 90 can include a plurality of N capacitors (e.g., capacitors C1, C2, . . . , CN), where N can represent an integer greater than one, 2-10, 10-20, 20-50, 50-100, or greater than 100.

Capacitor C1 can have a first terminal coupled to an amplifier output node 104 and a second terminal that is selectively coupled to a positive power supply line 100 (e.g., a power supply terminal on which positive power supply voltage Vdd is provided) or a ground power supply line 102 (e.g., a ground power supply terminal on which ground voltage Vss is provided) via a first capacitor switch S1. Capacitor C1 and switch S1 can represent amplifier circuit 70-1 in FIG. 3. Thus, if control signal b1 is asserted, then the oscillating signal can actively toggle switch S1. If, however, control signal b1 is deasserted, then capacitor C1 will be shunted to ground 102 via switch S1.

Similarly, capacitor C2 can have a first terminal coupled to the amplifier output node 104 and a second terminal that is selectively coupled Vdd or Vss via a second capacitor switch S2. Capacitor C2 and switch S2 can represent amplifier circuit 70-2 in FIG. 3. Thus, if control signal b2 is asserted, then the oscillating signal can actively toggle switch S2. If, however, control signal b2 is deasserted, then capacitor C2 will remain shunted to ground 102 via switch S2. Similarly, capacitor CN can have a first terminal coupled to the amplifier output node 104 and a second terminal that is selectively coupled Vdd or Vss via capacitor switch SN. Capacitor CN and switch SN can represent amplifier circuit 70-N in FIG. 3. Thus, if control signal bN is asserted, then the oscillating signal can actively toggle switch SN. If, however, control signal bN is deasserted, then capacitor CN remain shunted to ground 102 via switch SN. The term “capacitor switch” can refer to and be defined herein as a switch coupled in series with one of N capacitors within switched capacitor based RF amplifier circuitry 90.

In the example of FIG. 4, a matching circuit such as antenna matching circuit can be coupled between amplifier output node 104 and one or more antennas 42. Antenna matching circuit 106 can be configured to match the impedance of the antenna 42 with the output impedance of amplifier circuitry 90 to promote maximum power transfer in the transmit path. This is illustrative. If desired, one or more additional radio-frequency front-end components can be coupled between combiner 72 and antenna(s) 42 (see, e.g., front-end components 40 in FIG. 2).

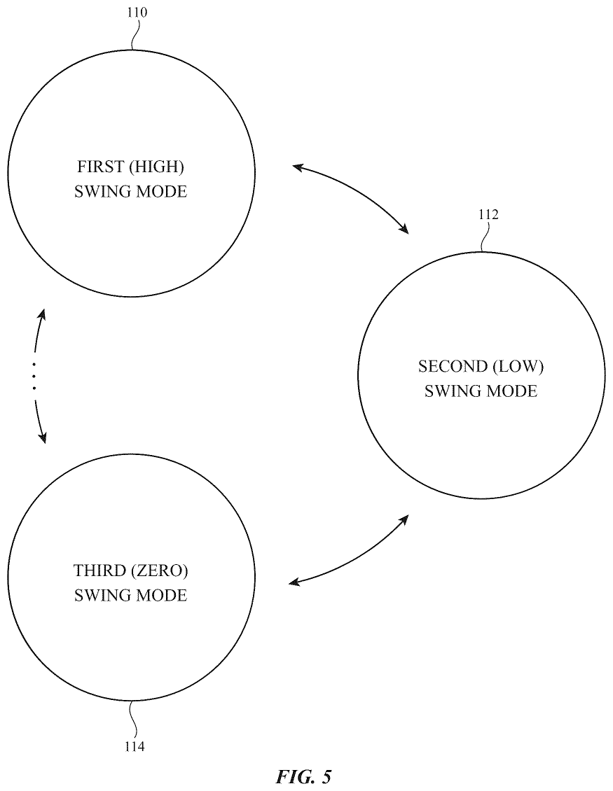

The capacitor switches (e.g., switches S1, S2, . . . , SN), sometimes referred to herein as capacitor switching circuits, can be operated in various swing modes. FIG. 5 is a diagram showing illustrative swing modes for operating one or more capacitor switching circuits in the switched capacitor based radio-frequency amplifier circuitry 90 of FIG. 4. As shown in FIG. 5, a capacitor switch can be operable in a first swing mode such as high swing mode 110, a second swing mode such as low swing mode 112, and a third swing mode such as zero-swing mode 114. When operated in the high swing mode 110, the capacitor switch can produce an output signal having a first voltage swing. When operated in the low swing mode 112, the capacitor switch can produce an output signal having a second voltage swing less than the first voltage swing. When operated in the zero-swing mode 114, the capacitor switch can produce an output signal that is maintained at a constant voltage level. The example of FIG. 5 in which a capacitor switch is operable among at least three different swing modes is illustrative. In general, a capacitor switch can be operable between at least two different swing modes, among three or more swing modes, among four or more swing modes, among five or more swing modes, or among any suitable number of swing modes.

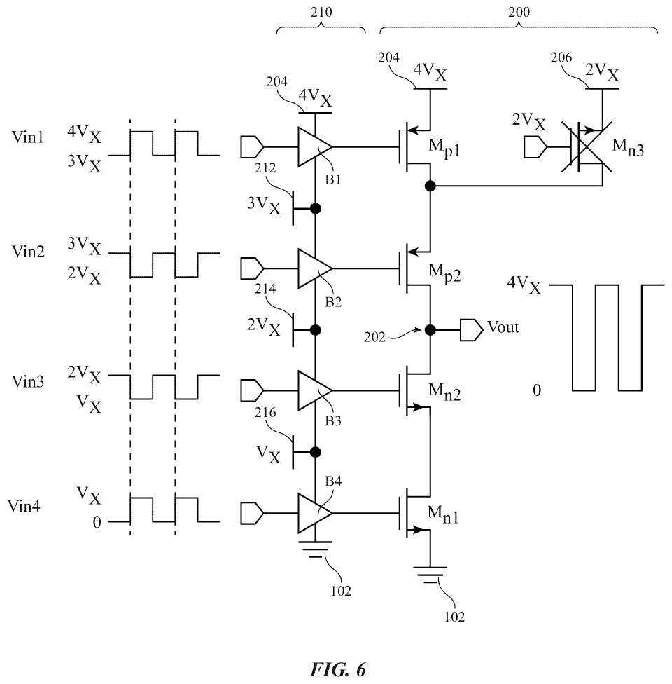

FIG. 6 is a circuit diagram of an illustrative capacitor switch such as capacitor switching circuit 200 that is configured to operate in a high swing mode (e.g., first swing mode 110 of FIG. 5). As shown in FIG. 6, capacitor switching circuit 220 can include a pull-down transistor Mn1, a first cascode transistor Mn2 coupled between an output node 202 and pull-down transistor Mn1, a pull-up transistor Mp1, a second cascode transistor Mp2 coupled between output node 202 and pull-up transistor Mp1, and an additional pull-up transistor Mn3. Transistors Mn1, Mn2, and Mn3 can be implemented as n-type transistors (e.g., n-channel metal-oxide-semiconductor or NMOS transistors), whereas transistor Mp1 and Mp2 can be implemented as p-type transistors (e.g., p-channel metal-oxide-semiconductor or PMOS transistors).

Pull-down transistor Mn1 may have a drain terminal coupled to output node 202 via first cascode transistor Mn2, a source terminal coupled to ground line 102, and a gate terminal. The terms “source” and “drain” are sometimes used interchangeably when referring to current-conducting terminals of a metal-oxide-semiconductor transistor. The source and drain terminals are therefore sometimes referred to as “source-drain” terminals (e.g., a transistor has a gate terminal, a first source-drain terminal, and a second source-drain terminal). The term “activate” with respect to a switch (or transistor) may refer to or be defined herein as an action that places the switch in an “on” or low-impedance state such that the two terminals of the switch are electrically connected to conduct current. Activating a switch can sometimes be referred to as turning on or closing a switch. The term “deactivate” with respect to a switch (or transistor) may refer to or be defined herein as an action that places the switch in an “off” or high-impedance state such that the two terminals of the switch/transistor are electrically disconnected with minimal leakage current. Deactivating a switch can sometimes be referred to as turning off or opening a switch.

Pull-up transistor Mp1 may have a drain terminal coupled to output node 202 via second cascode transistor Mp2, a source terminal coupled to a first power supply line 204 (e.g., a positive power supply terminal on which power supply voltage 4Vx is provided), and a gate terminal. Additional pull-up transistor Mn3 may have a drain terminal coupled to a node disposed between transistors Mp1 and Mp2, a source terminal coupled to a second power supply line 206 (e.g., a positive power supply terminal on which power supply voltage 2Vx is provided), and a gate terminal. An output voltage Vout may be produced on output node 202. Output node 202 can be coupled to a corresponding capacitor of switched capacitor based RF amplifier circuitry 90 (see FIG. 4).

If care is not taken, at least some of the transistors in capacitor switching circuit 200 can be subject to reliability issues. For instance, if transistors Mn2 and Mp2 are configured to receive fixed voltages during the high swing mode, then transistors Mn2 and Mp2 can be exposed to a heightened level of voltage stress at their drain and/or gate terminals and can also result in degraded power efficiency. It is within such context that the embodiments herein arise.

In accordance with some embodiments, capacitor switching circuit 200 can be driven by a chain of buffer circuits 210. Buffers 210 can represent a portion of buffer circuitry 64 in FIG. 3. Buffer circuits 210 can include a first buffer B1, a second buffer B2, a third buffer B3, and a fourth buffer B4 coupled together in series. In particular, the first buffer B1 can have a first power supply terminal coupled to first power supply line 204, a second power supply terminal coupled to power supply line 212 (e.g., a power supply line on which voltage 3Vx is provided), and an output coupled to the gate terminal of transistor Mp1. The second buffer B2 can have a first power supply terminal coupled to power supply line 212, a second power supply terminal coupled to power supply line 214 (e.g., a power supply line on which voltage 2Vx is provided), and an output coupled to the gate terminal of transistor Mp2. Third buffer B3 can have a first power supply terminal coupled to power supply line 214, a second power supply terminal coupled to power supply line 216 (e.g., a power supply line on which voltage Vx is provided), and an output coupled to the gate terminal of transistor Mn2. Fourth buffer B4 can have a first power supply terminal coupled to power supply line 216, a second power supply terminal coupled to ground 102, and an output coupled to the gate terminal of transistor Mn1. Coupled together in a chain, current flowing through the various buffers can be reused for improved power efficiency.

In the high swing mode, voltage 2Vx can be provided to the gate terminal of transistor Mn3 to deactivate transistor Mn3, as shown by the “X” through transistor Mn3. Voltage Vx can, for example be equal to 0.5 V, 0.6 V, 0.7 V, 0.5-0.7 V, 0.4-0.8 V, 0.5-1 V, or other suitable voltage. In arrangements where Vx is equal 0.6 V, 2Vx is equal to 1.2 V, 3Vx is equal to 1.8 V, and 4Vx is equal to 2.4 V. In the example of FIG. 6, buffer B1 can be configured to output a corresponding first input voltage Vin1 that toggles between 3Vx and 4Vx to the gate terminal of transistor Mp1. Buffer B2 can be configured to output a corresponding second input voltage Vin2 that toggles between 2Vx and 3Vx to the gate terminal of transistor Mp2. Buffer B3 can be configured to output a corresponding third input voltage Vin3 that toggles between Vx and 2Vx to the gate terminal of transistor Mn2. Buffer B4 can be configured to output a corresponding fourth input voltage Vin4 that toggles between 0 V and Vx to the gate terminal of transistor Mn1. As a result, capacitor switching circuit 200 can produce voltage Vout that toggles between 0 V and 4Vx at output node 202.

Configuring and operating the switching circuitry of FIG. 6 in this way can be technically advantageous and beneficial to distribute voltages evenly among the various transistors within circuit 200 so that the switching transistors Mn1, Mn2, Mp2, Mp1 and Mn3 will not be exposed to the elevated stress levels during the high swing mode. This also can enable a higher voltage swing at node 202 of FIG. 6. (e.g., from 0 to 4Vx), thus increasing the output power with improved power efficiency by keeping the switch driver swing at a lower level (Vx). Lowering the switch gate-source swing reduces the driver dynamic power consumption (CV²f). Employing a higher supply also has the advantage of being able to implement a lower loss matching network illustrated in FIG. 4, thus improving the efficiency even further. Moreover, the switch resistance becomes less significant because the impedance seen from the matching network increases when utilizing a higher supply swing at the output node.

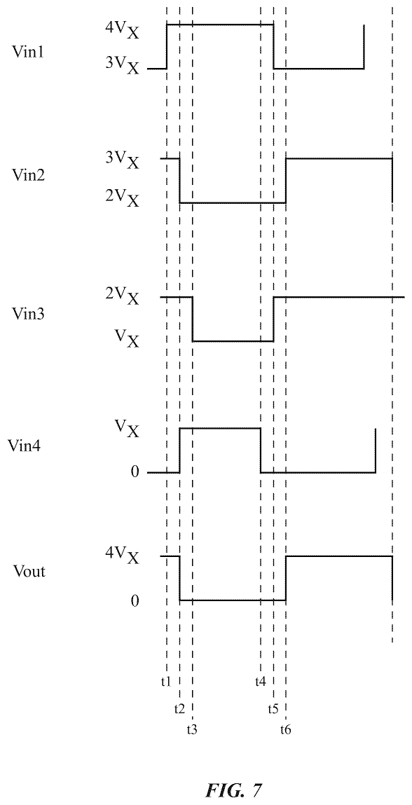

FIG. 7 is a timing diagram illustrating the operation of capacitor switching circuit 200 of FIG. 6 in the high swing mode. As shown in FIG. 7, signal Vin1 at the gate of transistor Mp1 can have a rising edge at time t1. Then, at time t2 after t1, signal Vin2 at the gate of transistor Mp2 can exhibit a falling edge. At the same time (t2), signal Vin4 at the gate of transistor Mn1 can exhibit a rising edge. This combination of waveforms can cause the output signal Vout to be driven low at time t2. At time t3 after t2, signal Vin3 at the gate of transistor Mn2 can exhibit a falling edge.

Later at time t4, signal Vin4 at the gate of transistor Mn1 can exhibit a falling edge. At time t5 after t4, signal Vin1 can exhibit a falling edge. At the same time (t5), signal Vin3 can exhibit a rising edge. Then at time t6 after t5, signal Vin2 can exhibit a rising edge, which then causes output signal Vout to be driven high. Configured in this way, signal Vin2 may be an inverted and delayed version of signal Vin1. Similarly, signal Vin3 may be an inverted and delayed version of signal Vin4. Moreover, the high phase of signal Vin4 (e.g., the time period during which transistor Mn1 is activated) does not overlap with the low phase of signal Vin1 (e.g., the time period during which transistor Mp1 is activated). Furthermore, signal Vin2 and Vin3 are timed such that the cascode transistors Mn2 and Mp2 do not experience any glitches across their gate/source/drain terminals.

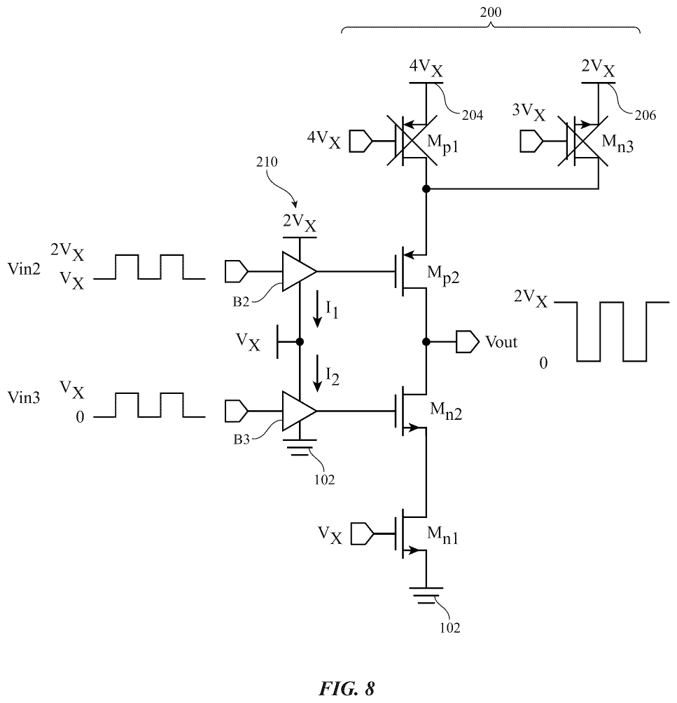

The configuration of FIG. 6 in which capacitor switching circuit 200 is operated in the high swing mode is exemplary. FIG. 8 shows capacitor switching circuit 200 being configured to operate in the low swing mode (e.g., mode 112 in FIG. 5). As shown in FIG. 8, during the low swing mode, pull-up transistor Mp1 may be deactivated by driving its gate to 4Vx. Meanwhile, transistor Mn3 can be activated by driving its gate terminal to 3Vx. The gate terminal of pull-down transistor Mn1 may be configured to receive voltage Vx. The gate terminal of cascode transistor Mp2 can be configured to receive a toggling voltage signal from buffer B2. The gate terminal of cascode transistor Mn2 can be configured to receive a toggling voltage signal from buffer B3. Buffers B2 and B3 may be part of buffer circuits 210.

Buffer B2 can have a first power supply terminal configured to receive voltage 2Vx, a second power supply terminal configured to receive voltage Vx, and an output coupled to the gate terminal of transistor Mp2. Buffer B3 can have a first power supply terminal configured to receive voltage Vx, a second power supply terminal coupled to ground, and an output coupled to the gate terminal of transistor Mn2. Coupled together in a chain, current flowing through the various buffers can be reused for improved power efficiency.

In the example of FIG. 8, buffer B2 can be configured to output a corresponding input voltage Vin2 that toggles between Vx and 2Vx to the gate terminal of transistor Mp2. Buffer B3 can be configured to output a corresponding input voltage Vin3 that toggles between 0 V and Vx to the gate terminal of transistor Mn2. As a result, capacitor switching circuit 200 can produce voltage Vout that toggles between 0 V and 2Vx at output node 202. Configuring and operating the switching circuitry of FIG. 8 in this way can be technically advantageous and beneficial to distribute voltages evenly among the various transistors within circuit 200 so that the cascode transistors Mn2 and Mp2 will be shielded from elevated stress levels during the low swing mode. While delivering 2Vx swing at the output providing a high output power, the gate/source voltage swing of the switches are at a lower voltage level (Vx). This helps to improve the driver power efficiency by reducing the dynamic power consumption (CV²f).

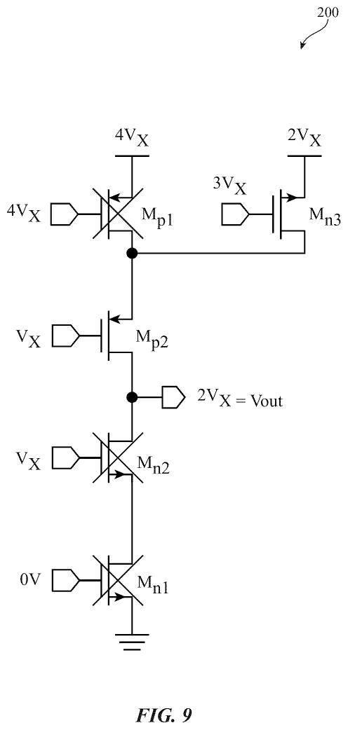

The configuration of FIG. 8 in which capacitor switching circuit 200 is operated in the low swing mode is exemplary. FIG. 9 shows capacitor switching circuit 200 being configured to operate in the zero-swing mode (e.g., mode 114 in FIG. 5). As shown in FIG. 9, during the zero (no) swing mode, pull-up transistor Mp1 may be deactivated by driving its gate to 4Vx. Meanwhile, transistor Mn3 can be activated by driving its gate terminal to 3Vx. Transistor Mp2 can be activated by driving its gate terminal to Vx. Pull-down transistor Mn1 can be deactivated by driving its gate terminal to 0 V. Cascode transistor Mn2 can also be deactivated by driving its gate terminal to Vx. As a result, capacitor switching circuit 200 can produce voltage Vout that is fixed at voltage level 2Vx (e.g., the output node is pulled up to 2Vx via transistors Mp2 and Mn3). Configuring and operating the switching circuitry of FIG. 9 in this way can be technically advantageous and beneficial to avoid having elevated stress on the capacitors connected to switching cells configured in the zero-swing mode.

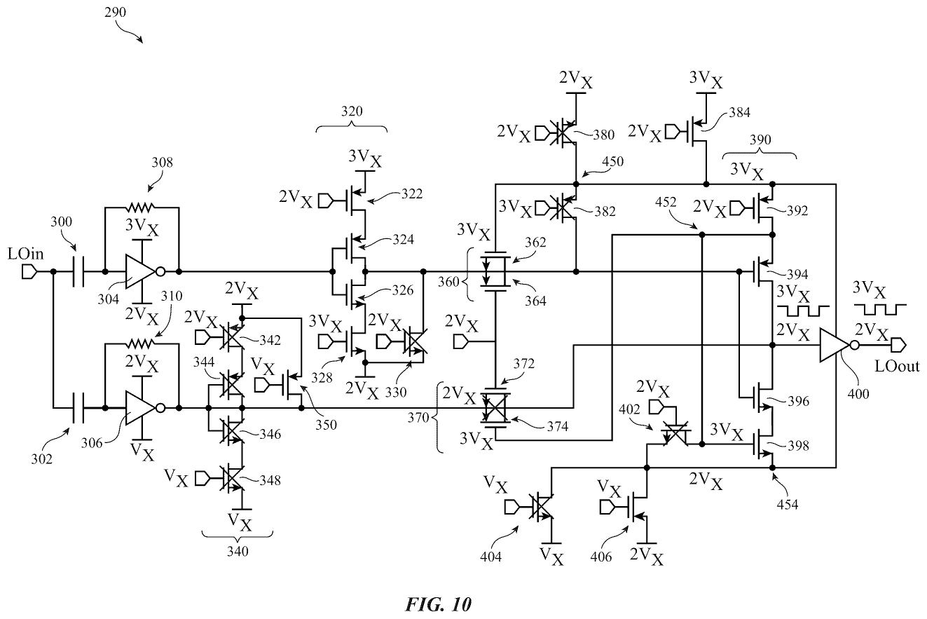

The cascode transistors Mp2 and Mn2 of capacitor switching circuit 200 can have gate terminals that are driven by buffers B2 and B3, respectively. These buffers driving the gate terminals of the cascode transistors are sometimes referred to as cascode driver circuits or cascode drivers. FIG. 10 is a circuit diagram of an illustrative cascode driver circuit such as cascode driver 290. Cascode driver 290 of FIG. 10 can be configured to drive the gate terminal of cascode transistor Mp2 during the high swing mode. As shown in FIG. 10, cascode driver 290 may have an input LOin configured to receive an oscillating signal, a first inverter 304 having an input coupled to LOin via capacitor 300, and a second inverter 306 having an input coupled to LOin via capacitor 302. The first inverter 304 may have power supply terminals coupled to 3Vx and 2Vx. The second inverter 306 may have power supply terminals coupled to 2Vx and Vx. A first feedback resistor 308 may be coupled across the input and output of inverter 304. A second feedback resistor 310 may be coupled across the input and output of inverter 306.

An inverting circuit 320 may be coupled to the output of inverter 304. Inverting circuit 320 may have p-type transistors 322 and 324 coupled in series with n-type transistors 326 and 328 between two power supply terminals coupled to 3Vx and 2Vx, respectively. Transistor 322 may have a gate terminal configured to receive voltage 2Vx. Transistor 328 may have a gate terminal configured to receive voltage 3Vx. Transistors 324 and 326 may have gate terminals shorted to the output of inverter 304. Inverting circuit 320 can also include an n-type transistor having a drain terminal coupled to an output of circuit 320, a source terminal coupled to 2Vx, and a gate terminal configured to receive voltage 2Vx.

An inverting circuit 340 may be coupled to the output of inverter 306. Inverting circuit 340 may have p-type transistors 342 and 344 coupled in series with n-type transistors 346 and 348 between two power supply terminals coupled to 2Vx and Vx, respectively. Transistor 342 may have a gate terminal configured to receive voltage 2Vx. Transistor 348 may have a gate terminal configured to receive voltage Vx. Transistors 344 and 346 may have gate terminals shorted to the output of inverter 306. Inverting circuit 340 can also include an p-type transistor having a drain terminal coupled to an output of circuit 340, a source terminal coupled to 2Vx, and a gate terminal configured to receive voltage Vx.

A transmission gate 360 may be coupled to the output of inverting circuit 320. Transmission gate 360 may include n-type transistor 362 and p-type transistor 364 coupled together in parallel. A transmission gate 370 may be coupled to the output of inverting circuit 340. Transmission gate 370 may include n-type transistor 372 and p-type transistor 374 coupled together in parallel. Transistors 364 and 372 may have gate terminals configured to receive voltage 2Vx.

Transistor 362 may have a gate terminal coupled to node 450. N-type transistor 380 may have a drain terminal coupled to node 450, a source terminal coupled to 2Vx, and a gate terminal configured to receive voltage 2Vx. P-type transistor 382 may have a source terminal coupled to node 450, a drain terminal coupled to an output of transmission gate 360, and a gate terminal configured to receive voltage 3Vx. P-type transistor 384 may have a drain terminal coupled to node 450, a source terminal coupled to 3Vx, and a gate terminal configured to receive voltage 2Vx.

Transistor 374 may have a gate terminal coupled to node 452. N-type transistor 402 may have a drain terminal coupled to node 452, a source terminal coupled to node 454, and a gate terminal configured to receive voltage 2Vx. N-type transistor 404 may have a drain terminal coupled to node 454, a source terminal coupled to Vx, and a gate terminal configured to receive voltage Vx. P-type transistor 406 may have a drain terminal coupled to node 454, a source terminal coupled to 2Vx, and a gate terminal configured to receive Vx.

Cascode driver 390 can further include inverting circuit 390 and inverter 400. Inverting circuit 390 may include p-type transistors 392 and 394 and n-type transistors 396 and 398 coupled in series between nodes 450 and 454. Transistor 392 may have a source terminal coupled to node 450, a drain terminal coupled to node 452, and a gate terminal configured to receive voltage 2Vx. Transistor 394 may have a source terminal coupled to node 452, a drain terminal coupled to the output of transmission gate 370, and a gate terminal coupled to the output of transmission gate 360. Transistor 396 may have a drain terminal coupled to the output of transmission gate 370, a source terminal, and a gate terminal coupled to the output of transmission gate 360. Transistor 398 may have a drain terminal coupled to the source terminal of transistor 396, a source terminal coupled to node 454, and a gate terminal coupled to node 452. Configured in this way, inverting circuit 390 may have an input coupled to the output of transmission gate 360 and an output coupled to an input of inverter 400.

Inverter 400 may further include a first power supply terminal coupled to node 450, a second power supply terminal coupled to node 454, and an output LOout. Configured in the way shown in FIG. 10, inverting circuit 340, transistor 330, transmission gate 370, transistors 380 and 382, and transistors 402 and 404 can be deactivated while the other components within driver 290 remain in use. As a result, inverter 400 can produce an output signal toggling between voltages 2Vx and 3Vx, which is consistent with the expected signal behavior of Vin2 during the high swing mode shown in FIG. 6.

Cascode driver 290 for driving the gate terminal of the p-type cascode transistor Mp2 during the high swing mode as shown in FIG. 10 is exemplary. A similar cascode driver can be configured to drive the gate terminal of the n-type cascode transistor Mn2 during the high swing mode. Such cascode driver driving transistor Mn2 can have the same structure as that illustrated in FIG. 10, except the instances of 3Vx are changed to 2Vx, the instances of 2Vx are changed to Vx, and the instances of Vx are changed to ground.

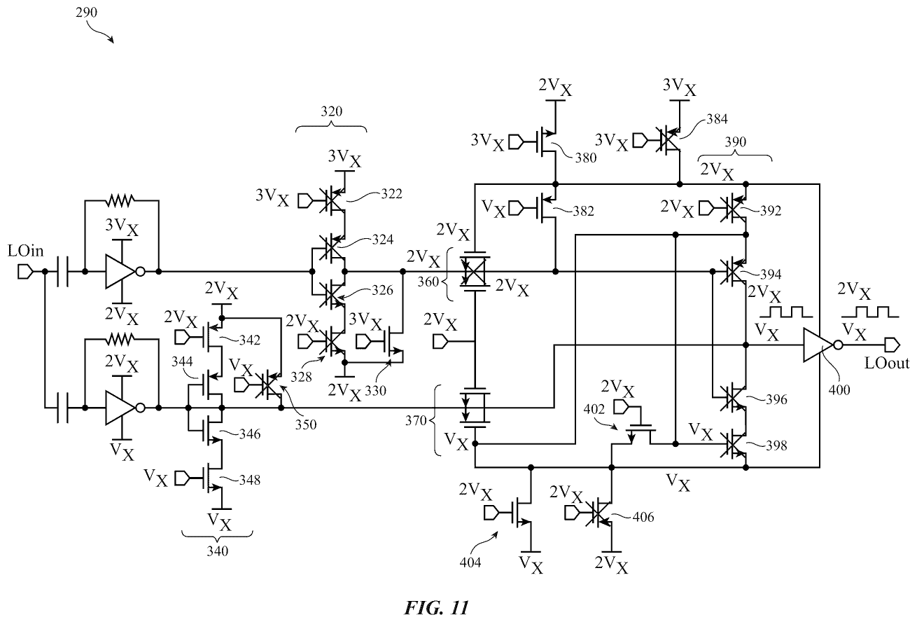

FIG. 11 is a circuit diagram showing cascode driver 290 for driving cascode transistor Mp2 during the low swing mode. The configuration of inverters 304 and 306 and inverting circuit 340 remains unchanged. However, the gate terminal of transistor 322 can be configured to receive voltage 3Vx. The gate terminal of transistor 328 can be configured to receive voltage 2Vx. The gate terminal of transistor 330 can be configured to receive voltage 3Vx. The gate terminal of transistor 380 can be configured to receive voltage 3Vx. The gate terminal of transistor 382 can be configured to receive voltage Vx. The gate terminal of transistor 384 can be configured to receive voltage 3Vx. The gate terminal of transistor 404 can be configured to receive voltage 2Vx. The gate terminal of transistor 406 can be configured to receive voltage 2Vx.

Configured in the arrangement of FIG. 11, inverting circuit 320, transistor 350, transmission gate 360, transistor 406, transistor 384, and inverting circuit 390 can be deactivated while the other components within driver 290 can remain in use (e.g., the low swing mode has one fewer inverting stage since inverting circuit 390 is now disabled). As a result, inverter 400 can produce an output signal toggling between voltages Vx and 2Vx, which is consistent with the expected signal behavior of Vin2 during the low swing mode shown in FIG. 8.

Cascode driver 290 for driving the gate terminal of the p-type cascode transistor Mp2 during the low swing mode as shown in FIG. 11 is exemplary. A similar cascode driver can be configured to drive the gate terminal of the n-type cascode transistor Mn2 during the low swing mode. Such cascode driver driving transistor Mn2 can have the same structure as that illustrated in FIG. 11, except the instances of 3Vx are changed to 2Vx, the instances of 2Vx are changed to Vx, and the instances of Vx are changed to ground.

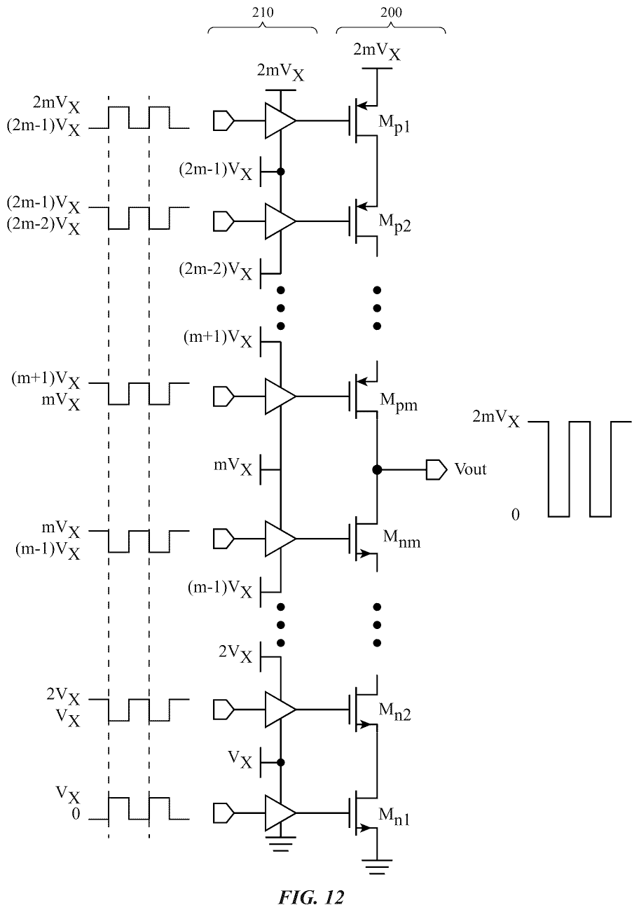

The embodiments shown in at least FIGS. 6, 8, and 9 in which switching circuit 200 includes two cascode transistor Mn2 and Mp2 are illustrative. FIG. 12 shows a more general circuit topology of capacitor switching circuit 200 that includes more than two cascode transistors. As shown in FIG. 12, the pull-down path can include (m−1) cascode transistors Mn2-Mnm (e.g., n-type or NMOS transistors), whereas the pull-up path can similarly include (m−1) cascode transistors Mp2-Mpm (e.g., p-type or PMOS transistors). Integer m can be any value greater than 2, 3-5, 5-10, or greater than 10.

The transistors in capacitor switching circuit 200 can be driven by a chain of buffers 210. The chain of buffers can have power supply terminals connected together to support current reuse. The buffer driving transistor Mp1 can output a driver voltage that toggles between (2m−1)Vx and 2mVx. The buffer driving transistor Mp2 can output a driver voltage that toggles between (2m−2)Vx and (2m−1)Vx. The buffer driving transistor Mpm can output a driver voltage that toggles between Vx and (m+1)Vx. The buffer driving transistor Mnm can output a driver voltage that toggles between (m−1)Vx and mVx. The buffer driving transistor Mn2 can output a driver voltage that toggles between Vx and 2Vx. The buffer driving transistor Mn1 can output a driver voltage that toggles between 0 V and Vx. As a result, switching circuit 200 can generate a corresponding output voltage Vout that toggles between 0 V and 2mVx during the high swing mode. Configured in the way shown in FIG. 12, the voltages are evenly distributed across the drain-source terminals of all the transistors to mitigate potential reliability issues. If desired, the cascode driver of the type described in connection with FIGS. 10 and 11 can similarly be modified to include an increased number of cascode transistors.

The methods and operations described above in connection with FIGS. 1-12 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

The foregoing is exemplary and various modifications can be made to the described embodiments. The foregoing embodiments may be implemented individually or in any combination.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

What is claimed is:

1. Amplifier circuitry comprising:
a plurality of capacitors; and
at least one capacitor switching circuit coupled to a capacitor in the plurality of capacitors, wherein the at least one capacitor switching circuit comprises:
a pull-up transistor configured to receive a first voltage signal; and
a first cascode transistor coupled between the pull-up transistor and an output of the at least one capacitor switching circuit, the first cascode transistor being configured to receive a second voltage signal that toggles while the at least one capacitor switching circuit is configured to operate in at least a first mode and a second mode different than the first mode.

2. The amplifier circuitry of claim 1, wherein:
the first voltage signal toggles between a first voltage level and a second voltage level during the first mode; and
the second voltage signal toggles between the second voltage level and a third voltage level less than the second voltage level during the second mode.

3. The amplifier circuitry of claim 2, wherein:
the first voltage signal is fixed at the first voltage level during the second mode; and
the second voltage signal toggles between the third voltage level and a fourth voltage level less than the third voltage level during the second mode.

4. The amplifier circuitry of claim 3, wherein:
the at least one capacitor switching circuit is further configured to operate in a third mode;
the first voltage signal is fixed at the first voltage level during the third mode; and
the second voltage signal is fixed at the fourth voltage level during the third mode.

5. The amplifier circuitry of claim 4, wherein the at least one capacitor switching further comprises:
a n-type transistor having a drain terminal coupled to a node between the pull-up transistor and the first cascode transistor, a source terminal configured to receive a voltage at the third voltage level, and a gate terminal configured to receive a voltage that is equal to the third voltage level during the first mode and equal to the second voltage level during the second and third modes.

6. The amplifier circuitry of claim 3, wherein the at least one capacitor switching further comprises:
a pull-down transistor configured to receive a fourth voltage signal; and
a second cascode transistor coupled between the pull-down transistor and the output of the at least one capacitor switching circuit, the second cascode transistor being configured to receive a third voltage signal.

7. The amplifier circuitry of claim 6, wherein:
the third voltage signal toggles between the third voltage level and the fourth voltage level during the first mode; and
the fourth voltage signal toggles between the fourth voltage level and a fifth voltage level less than the fourth voltage level during the first mode.

8. The amplifier circuitry of claim 7, wherein:
the third voltage signal toggles between the fourth voltage level and the fifth voltage level during the second mode; and
the fourth voltage signal is fixed at the fourth voltage level during the second mode.

9. The amplifier circuitry of claim 3, wherein:
the at least one capacitor switching circuit is further configured to operate in a third mode;
the third voltage signal is fixed at the fourth voltage level during the third mode; and
the fourth voltage signal is fixed at the fifth voltage level during the third mode.

10. The amplifier circuitry of claim 6, further comprising:
a first buffer coupled to a gate terminal of the pull-up transistor;
a second buffer coupled to a gate terminal of the first cascode transistor and having a power supply terminal coupled to the first buffer;
a third buffer coupled to a gate terminal of the second cascode transistor and having a power supply terminal coupled to the second buffer; and
a fourth buffer coupled to a gate terminal of the pull-down transistor and having a power supply terminal coupled to the third buffer.

11. The amplifier circuitry of claim 10, wherein the first buffer comprises:
a first inverter configured to receive an oscillating signal;
a second inverter configured to receive the oscillating signal;
a first transmission gate coupled to the first inverter;
a second transmission gate coupled to the second inverter; and
an inverting circuit having an input coupled to the first transmission gate and an output coupled to the second transmission gate, wherein the inverting circuit is activated during the first mode and is deactivated during the second mode.

12. A method of operating a switching circuit coupled to one of a plurality of capacitors in a radio-frequency amplifier, the method comprising:
conveying a first voltage signal to a gate terminal of a pull-up transistor;
conveying a second voltage signal to a gate terminal of a first cascode transistor coupled between the pull-up transistor and an output of the switching circuit;
conveying a third voltage signal to a gate terminal of a second cascode transistor; and
conveying a fourth voltage signal to a gate terminal of a pull-down transistor, wherein the second voltage signal and the third voltage signal are toggled between different voltage levels during at least a first mode of the switching circuit.

13. The method of claim 12, further comprising:
toggling the first voltage signal between first and second voltage levels during the first mode;
toggling the second voltage signal between the second voltage level and a third voltage level less than the second voltage level during the first mode;
toggling the third voltage signal between the third voltage level and a fourth voltage level less than the third voltage level during the first mode; and
toggling the fourth voltage signal between the fourth voltage level and a fifth voltage level less than the fourth voltage level during the first mode.

14. The method of claim 13, further comprising:
fixing the first voltage signal at the first voltage level during a second mode different than the first mode;
toggling the second voltage signal between the third and fourth voltage levels during the second mode;
toggling the third voltage signal between the fourth and fifth voltage levels during the second mode; and
fixing the fourth voltage signal at the fourth voltage level during the second mode.

15. The method of claim 14, further comprising:
fixing the first voltage signal at the first voltage level during a third mode different than the first and second modes;
fixing the second voltage signal at the fourth voltage level during the third mode;
fixing the third voltage signal at the fourth voltage level during the third mode; and
fixing the fourth voltage signal at the fifth voltage level during the third mode.

16. The method of claim 15, further comprising:
outputting a voltage signal that toggles between the first and fifth voltage levels during the first mode;
outputting a voltage signal that toggles between the third and fifth voltage levels during the second mode; and
outputting a voltage signal that is fixed at the third voltage level during the third mode.

17. A switching circuit comprising:
an output coupled to one of a plurality of capacitors;
a pull-up transistor;
a pull-down transistor; and
two or more cascode transistors coupled in series between the pull-up and pull-down transistors and operable to receive time-varying voltage signals.

18. The switching circuit of claim 17, wherein during a first swing mode:
the pull-up transistor is configured to receive a first voltage signal toggling between a first voltage level and a second voltage level;
a first of the cascode transistors is configured to receive a second voltage signal toggling between the second voltage level and a third voltage level less than the second voltage level;
a second of the cascode transistors is configured to receive a third voltage signal toggling between the third voltage level and a fourth voltage level less than the third voltage level; and
the pull-down transistor is configured to receive a fourth voltage signal toggling between the fourth voltage level and a fifth voltage level less than the fourth voltage level.

19. The switching circuit of claim 18, wherein during a second swing mode different than the first swing mode:
the first voltage signal is fixed at the first voltage level;
the second voltage signal toggles between the third and fourth voltage levels;
the third voltage signal toggles between the fourth and fifth voltage levels; and
the fourth voltage signal is fixed at the fourth voltage level.

20. The switching circuit of claim 19, wherein during a third swing mode different than the first and second swing modes:
the first voltage signal is fixed at the first voltage level;
the second voltage signal is fixed at the fourth voltage level;
the third voltage signal is fixed at the fourth voltage level; and
the fourth voltage signal is fixed at the fifth voltage level.
